(19) United States
(12) Patent Application Publication
(10) Pub. No.: US 2020/0219761 A1
(43) Pub. Date: Jul. 9, 2020

(54) METHOD OF FORMING SEMICONDUCTOR STRUCTURE

(71) Applicant: XIA TAI XIN SEMICONDUCTOR (QING DAO) LTD., Qingdao (CN)

(72) Inventors: JONG-MOO CHOI, Singapore (SG); HEUNG-WOO PARK, Singapore (SG); SUNG-KI KIM, Singapore (SG)

(21) Appl. No.: 16/679,338

(22) Filed: Nov. 11, 2019

Related U.S. Application Data
(60) Provisional application No. 62/784,553, filed on Dec. 24, 2018.
(60) Provisional application No. 62/784,554, filed on Dec. 24, 2018.

(51) Int. Cl. H01L 21/762; H01L 21/3205; H01L 21/321; H01L 21/3213; H01L 21/28; H01L 29/06; H01L 29/423

(52) U.S. Cl. CPC H01L 21/76235; H01L 21/32055; H01L 21/32105; H01L 29/42368; H01L 21/28229; H01L 29/0649; H01L 29/4236; H01L 21/32134

(57) ABSTRACT

A method of forming an oxide structure is disclosed. The method includes forming trenches on a top surface of a substrate and performing a surface treatment process on the substrate. The surface treatment includes forming an amorphous layer on the substrate, removing a portion of the amorphous layer to form a liner layer, and forming a dielectric liner on the liner layer. The liner layer formed are substantially uniform in thickness to prevent contamination and pinhole defects on the oxide structure.

### CROSS-REFERENCES TO RELATED APPLICATIONS

This application claims the benefit of U.S. Provisional Patent Application No. 62/784,553 filed on Dec. 24, 2018 and U.S. Provisional Patent Application No. 62/784,554 filed on Dec. 24, 2018, which is hereby incorporated by reference herein and made a part of specification.

### BACKGROUND

### 1. Field

The present disclosure generally relates to method of forming semiconductor structure, and more particularly, method of forming oxide structure in semiconductor structure.

### 2. Related Art

In semiconductor device manufacturing, a defective amorphous layer results in contamination and pinhole defects on the oxide structure formed over amorphous layer. Thus, there is a need to develop a process to form a continuously uniform amorphous layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a flowchart of a method of forming an oxide structure according to some embodiments of the instant disclosure;

FIG. 2 illustrates a flowchart of a method of forming an oxide structure according to some embodiments of the instant disclosure;

FIG. 3A-3D illustrates a cross section of a semiconductor structure according to some embodiments of the instant disclosure;

FIG. 4A-4D illustrates a cross section of a semiconductor structure according to some embodiments of the instant disclosure; and

FIG. 5 illustrates a cross section of a semiconductor structure according to some embodiments of the instant disclosure.

### DETAILED DESCRIPTION

The present disclosure will now be described more fully hereinafter with reference to the accompanying drawings, in which exemplary embodiments of the disclosure are shown. This disclosure may, however, be embodied in many different forms and should not be construed as limited to the exemplary embodiments set forth herein. Rather, these exemplary embodiments are provided so that this disclosure will be thorough and complete, and will fully convey the scope of the disclosure to those skilled in the art. Like reference numerals refer to like elements throughout.

The terminology used herein is for the purpose of describing particular exemplary embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

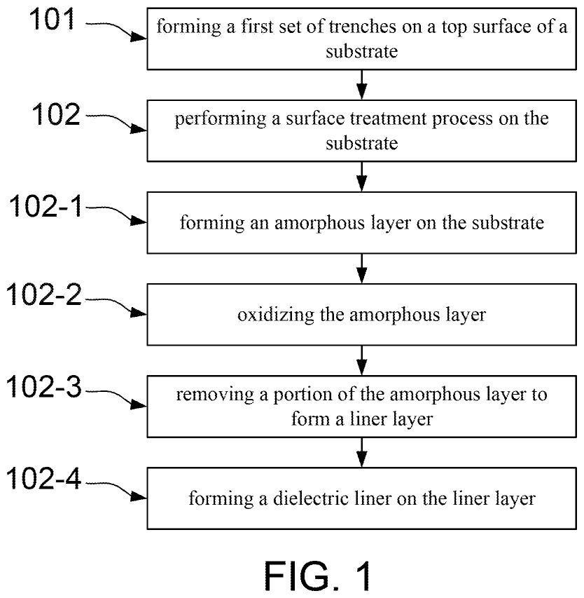

FIG. 1 illustrates a flowchart of a method of forming an oxide structure according to some embodiments of the instant disclosure. The method includes forming a first set of trenches on a top surface of a substrate (101) and performing a surface treatment process on the substrate (102). The method of forming the surface treatment includes forming an amorphous layer on the substrate (102-1), oxidizing the amorphous layer (102-2), removing a portion of the amorphous layer to form a liner layer (102-3), and forming a dielectric liner on the liner layer (102-4). During the process, the amorphous layer is thicker than the liner layer. In some embodiments, the method further comprises forming a second set of trenches on a top surface of a substrate. In some embodiments, after the surface treatment process, a conductive material is disposed over the dielectric liner layer to fill the trenches on the substrate.

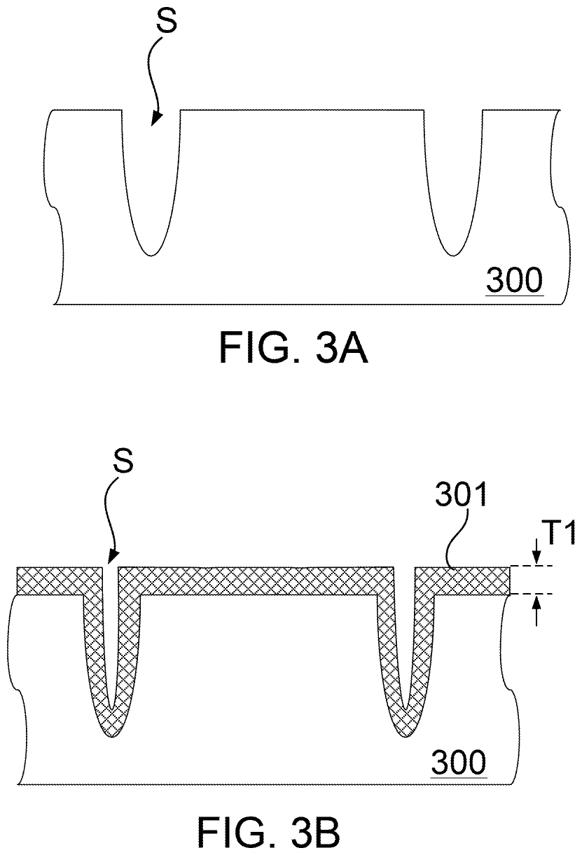

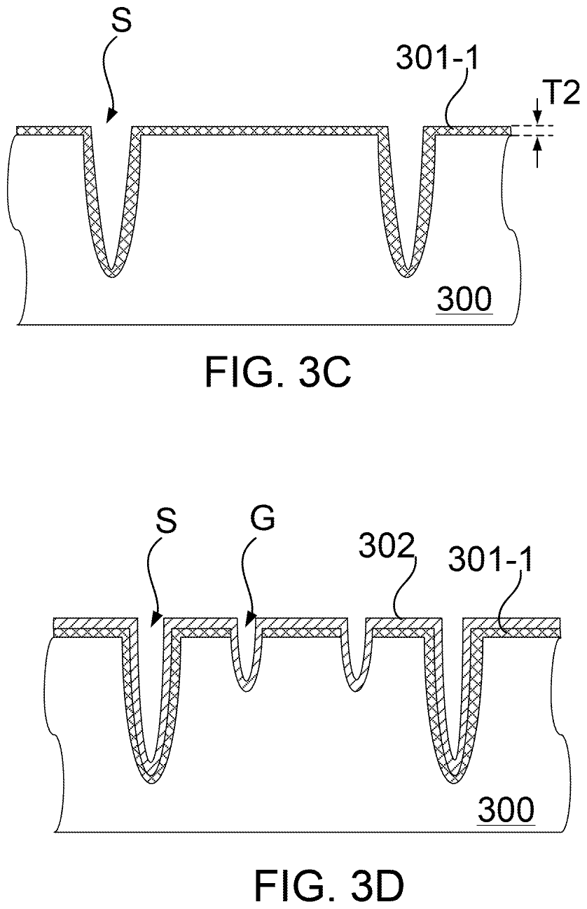

FIG. 3A-3D illustrates a cross section of a semiconductor structure according to some embodiments of the instant disclosure. FIG. 3A-3D shows the cross section of the semiconductor structure during the process of forming an oxide structure. As shown in FIG. 3A, a substrate 300 is provided. In some embodiments, a first set of trenches S formed on the substrate 300. The first set of trenches S does not penetrate through the bottom surface of the substrate 300. Afterwards, a surface treatment process is performed on the substrate 300.

As shown in FIG. 3B, an amorphous layer 301 is formed on the substrate 300. In some embodiments, the amorphous layer 301 has a uniform thickness T1 along the top surface of the substrate 300 and the walls of the first set of trenches S. In some embodiments, the thickness T1 is about 100 Å. In some embodiments, the thickness T1 is less than about 100 Å. In some embodiments, the thickness T1 is greater than about 30 Å. In some embodiments, the thickness T1 ranges from about 40 Å to about 100 Å. In some embodiments, the thickness T1 ranges from about 90 Å to about 150 Å. The amorphous layer 301 may include organic or inorganic materials. The amorphous layer 301 may include amorphous silicon. The amorphous layer 301 may include at least one of the materials, such as thin film lubricants, metallic glasses, polymers, and gels. In some embodiments the amorphous layer 301 is formed on the substrate 300 by depositing an amorphous material on the top surface of the substrate using chemical vapor deposition.

In some embodiments, the amorphous layer 301 is oxidized. In some embodiments, the amorphous layer 301 is oxidized through dry oxidation using oxygen (O₂). In some embodiments, the amorphous layer is oxidized through wet oxidation using water (H₂O). In some embodiments, removing the portion of the amorphous layer 301 to form the liner layer 301-1 includes etching an oxidized portion of the amorphous layer 301 using hydrogen fluoride (HF) solution to form the liner layer 301-1.

In some embodiments, removing the portion of the amorphous layer 301 to form the liner layer 301-1 includes etching the portion of the amorphous layer 301 to form the liner layer 301-1. In some embodiments, the wet etching process uses Standard Cleaning 1 (SC1) etchant. The SC1 etchant includes at least one of NH₄OH, H₂O₂, and di-ionized water. In some embodiments, the H₂O₂ is used to oxidize the amorphous layer 301 and the NH₄OH is used to remove the oxidized part of the amorphous layer 301 to form the liner layer 301-1. In some embodiments, the wet etching process using hydrofluoric acid (HF) etchant. The hydrofluoric acid (O₃_HF) etchant includes O₃ water and HF. In some embodiments, the O₃ is used to oxidize the amorphous layer 301 and the HF is used to remove the oxidized part of the amorphous layer 301 to form the liner layer 301-1.

As shown in FIG. 3C, a portion of the amorphous layer 301 is removed to form a liner layer 301-1. In some embodiments, the liner layer 301-1 has a uniform thickness T2 along the top surface of the substrate 300 and the walls of the first set of trenches S. In some embodiments, the thickness T2 is about 30 Å. In some embodiments, the thickness T2 is less than about 30 Å. In some embodiments, the thickness T2 is greater than about 20 Å. In some embodiments, the thickness T2 ranges from about 20 Å to about 30 Å. In some embodiments, the thickness T2 ranges from about 20 Å to about 40 Å. The thickness T1 of the amorphous layer 301 is about 3 to 5 times a thickness T2 of the liner layer 301-1.

As shown in FIG. 3D, a second set of trenches G are formed on a top surface of a substrate 300. Then, a dielectric liner 302 is formed on the liner layer 301-1. The dielectric liner 302 is disposed within the first set of trenches S. The dielectric liner 302 is further disposed in the second set of trenches G. In some embodiments, the dielectric liner 302 disposed in the second set of trenches G is directly in contact with the surface of the substrate 300. In some embodiments, the first set of trenches S are used for forming shallow trench isolations (STI) and the second set of trenches G are used for forming trench gates.

In some embodiments, a width of an opening of the first set of trenches S is greater than a width of opening of the second set of trenches G. In some embodiments, a distance of a bottom of the first set of trenches S from the top surface of the substrate 300 are greater than a distance of a bottom of the second set of trenches G from the top surface of the substrate 300. In some embodiments, a distance of a bottom of the first set of trenches S from the top surface of the substrate 300 are the same as a distance of a bottom of the second set of trenches G from the top surface of the substrate 300.

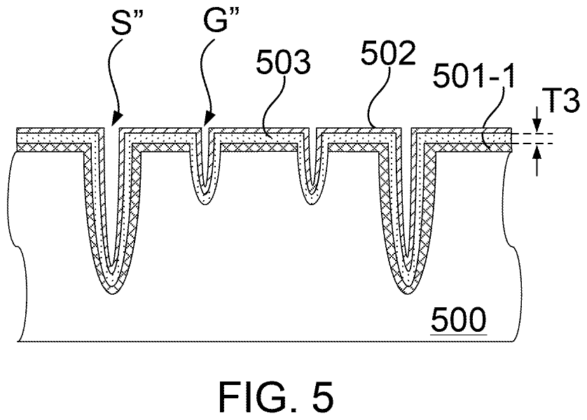

In some embodiments, before a dielectric liner is formed on the liner layer, the process performing a surface treatment process on the substrate are repeated after the process shown in 3C. Instead of the structure in FIG. 3D, the structure in FIG. 5 is formed. FIG. 5 illustrates a cross section of a semiconductor structure according to some embodiments of the instant disclosure. A supplement liner layer 503 is formed on the first set of trenches S″ and the second set of trenches G″. The supplement liner layer 503 may be in direct contact with the surface of the liner layer 501-1 within the first set of trenches S″. The supplement liner layer 503 may be in direct contact with the surface of the substrate 500 within the second set of trenches G″. In some embodiments, the first set of trenches S″ are used for forming shallow trench isolations (STI) and the second set of trenches G″ are used for forming trench gates.

In some embodiments, the thickness T3 of the supplement liner layer 503 is about 30 Å. In some embodiments, the thickness T3 is less than about 30 Å. In some embodiments, the thickness T3 is greater than about 20 Å. In some embodiments, the thickness T3 ranges from about 20 Å to about 30 Å. In some embodiments, the thickness T3 ranges from about 20 Å to about 40 Å. In some embodiments, total thickness of the supplement liner layer 503 and the liner layer 501-1 ranges from about 40 Å to about 80 Å.

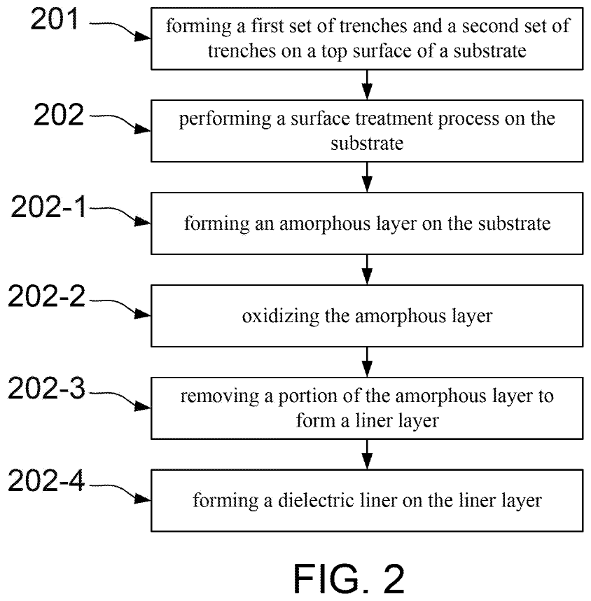

FIG. 2 illustrates a flowchart of a method of forming an oxide structure according to some embodiments of the instant disclosure. The method includes forming a first set of trenches and a second set of trenches on a top surface of a substrate (201) and performing a surface treatment process on the substrate (202). The method of performing the surface treatment includes forming an amorphous layer on the substrate (202-1), oxidizing the amorphous layer (202-2), removing a portion of the amorphous layer to form a liner layer (202-3), and forming a dielectric liner on the liner layer (202-4). In some embodiments, the first set of trenches and the second set of trenches are formed simultaneously. During the process, the amorphous layer is thicker than the liner layer. In some embodiments, a conductive material is disposed over the dielectric liner layer to fill the trenches on the substrate.

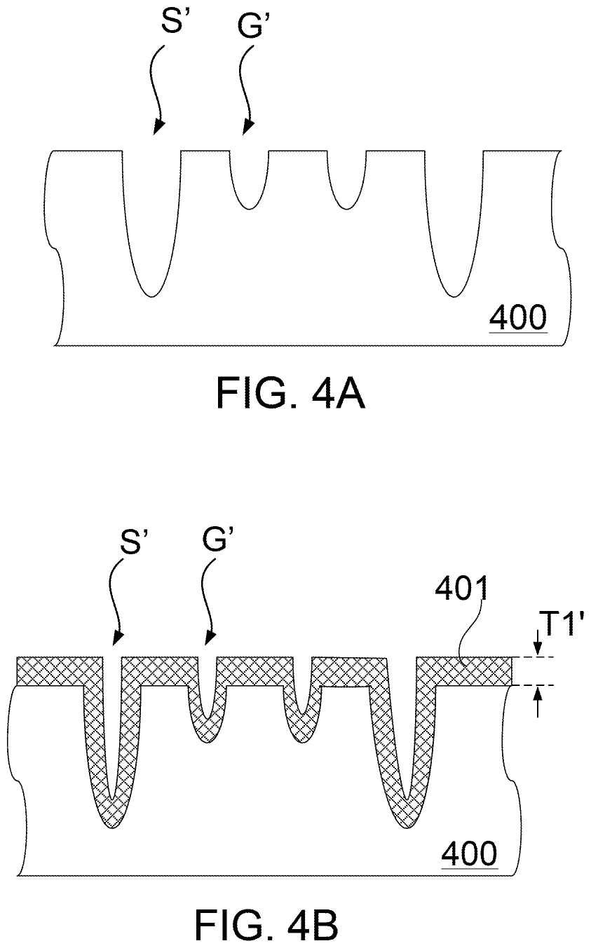

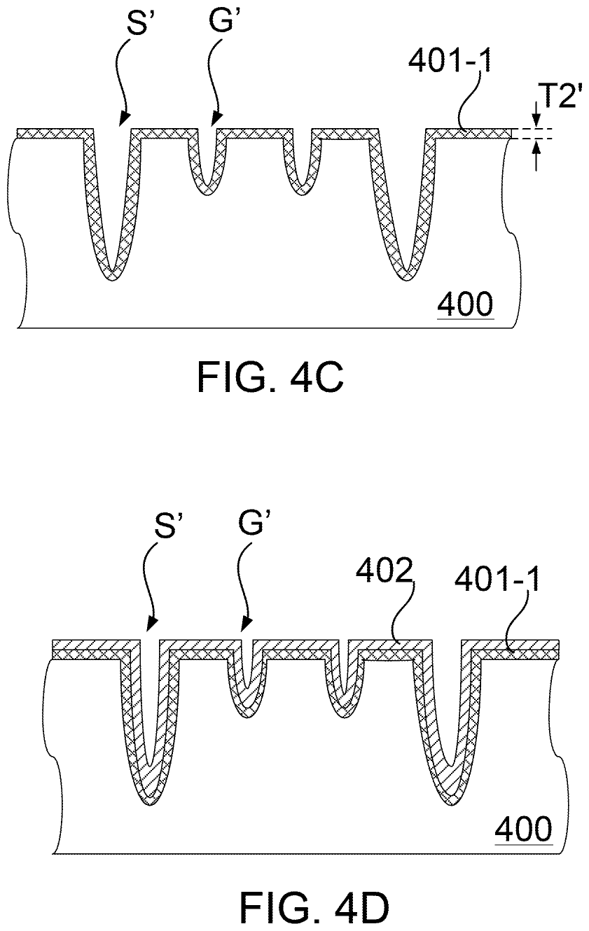

FIG. 4A-4D illustrates a cross section of a semiconductor structure according to some embodiments of the instant disclosure. FIG. 4A-4D shows the cross section of the semiconductor structure during the process of forming an oxide structure. As shown in FIG. 4A, a substrate 400 is provided. In some embodiments, a first set of trenches S′ and a second set of trenches G′ formed on the substrate 400. The first set of trenches S′ and the second set of trenches G′ does not penetrate through the bottom surface of the substrate 400. Afterwards, a surface treatment process is performed on the substrate 400.

In some embodiments, a width of an opening of the first set of trenches S′ is greater than a width of opening of the second set of trenches G′. In some embodiments, a distance of a bottom of the first set of trenches S′ from the top surface of the substrate 400 is greater than a distance of a bottom of the second set of trenches G′ from the top surface of the substrate 400. In some embodiments, a distance of a bottom of the first set of trenches S′ from the top surface of the substrate 400 are the same as a distance of a bottom of the second set of trenches G′ from the top surface of the substrate 400.

As shown in FIG. 4B, an amorphous layer 401 is formed on the substrate 400. In some embodiments, the amorphous layer 401 has a uniform thickness T1′ along the top surface of the substrate 400, the walls of the first set of trenches S′, and the walls of the second set of trenches G′. In some embodiments, the thickness T1′ is about 100 Å. In some embodiments, the thickness T1′ is less than about 100 Å. In some embodiments, the thickness T1′ is greater than about 30 Å. In some embodiments, the thickness T1′ ranges from about 40 Å to about 100 Å. In some embodiments, the thickness T1′ ranges from about 90 Å to about 150 Å. The amorphous layer 401 may include organic or inorganic materials. The amorphous layer 401 may include amorphous silicon. The amorphous layer 301 may include at least one of the materials, such as thin film lubricants, metallic glasses, polymers, and gels.

In some embodiments, the amorphous layer 401 is oxidized. In some embodiments, the amorphous layer 401 is oxidized through dry oxidation using oxygen (O₂). In some embodiments, the amorphous layer is oxidized through wet oxidation using water (H₂O). In some embodiments, removing the portion of the amorphous layer 401 to form the liner layer 401-1 includes etching an oxidized portion of the amorphous layer 401 using hydrogen fluoride (HF) solution to form the liner layer 401-1.

In some embodiments, removing the portion of the amorphous layer 401 to form the liner layer 401-1 includes etching the portion of the amorphous layer 401 to form the liner layer 401-1. In some embodiments, the wet etching process uses Standard Cleaning 1 (SC1) etchant. The SC1 etchant includes at least one of NH₄OH, H₂O₂, and di-ionized water. In some embodiments, the H₂O₂ is used to oxidize the amorphous layer 401 and the NH₄OH is used to remove the oxidized part of the amorphous layer 401 to form the liner layer 401-1. In some embodiments, the wet etching process using hydrofluoric acid (HF) etchant. The hydrofluoric acid (O₃_HF) etchant includes O₃ water and HF. In some embodiments, the O₃ is used to oxidize the amorphous layer 401 and the HF is used to remove the oxidized part of the amorphous layer 401 to form the liner layer 401-1.

As shown in FIG. 4C, a portion of the amorphous layer 401 is removed to form a liner layer 401-1. In some embodiments, the liner layer 401-1 has a uniform thickness T2′ along the top surface of the substrate 400 and the walls of the first set of trenches S′. In some embodiments, the thickness T2′ is about 30 Å. In some embodiments, the thickness T2′ is less than about 30 Å. In some embodiments, the thickness T2 is greater than about 20 Å. In some embodiments, the thickness T2′ ranges from about 20 Å to about 30 Å. In some embodiments, the thickness T2′ ranges from about 20 Å to about 40 Å. The thickness T1′ of the amorphous layer 401 is about 3 to 5 times a thickness T2′ of the liner layer 301-1.

As shown in FIG. 4D, a dielectric liner 402 is formed on the liner layer 401-1. The dielectric liner 402 is disposed within the first set of trenches S′ and the second set of trenches G′. In some embodiments, the first set of trenches S′ are used for forming shallow trench isolations (STI) and the second set of trenches G′ are used for forming trench gates.

Accordingly, one aspect of the instant disclosure provides a method of forming an oxide structure that comprises forming a first set of trenches on a top surface of a substrate; and performing a surface treatment on the substrate. The surface treatment process comprises forming an amorphous layer on the substrate; etching a portion of the amorphous layer to form a liner layer, wherein the amorphous layer is thicker than the liner layer; and disposing a dielectric material on the liner layer.

In some embodiments, the method further comprises forming a second set of trenches on a top surface of a substrate.

In some embodiments, a distance of a bottom of the first set of trenches from the top surface of the substrate are greater than a distance of a bottom of the second set of trenches from the top surface of the substrate.

In some embodiments, the first set of trenches and the second set of trenches are formed simultaneously.

In some embodiments, the method further comprises repeating the surface treatment after forming the second set of trenches.

In some embodiments, a width of an opening of the first set of trenches is greater than a width of opening of the second set of trenches.

In some embodiments, forming the amorphous layer on the substrate is depositing an amorphous material on the top surface of the substrate using chemical vapor deposition.

In some embodiments, the first set of trenches does not penetrate through a bottom surface of the substrate.

In some embodiments, a thickness of the amorphous layer is at least 100 Å.

In some embodiments, a thickness of the liner layer is less than 30 Å.

In some embodiments, a thickness of the amorphous layer is about 3 to 5 times a thickness of the liner layer.

In some embodiments, etching the portion of the amorphous layer to form the liner layer includes wet etching process using Standard Cleaning 1 (SC1) etchant.

In some embodiments, the SC1 etchant includes at least one of NH₄OH, H₂O₂, and di-ionized water.

In some embodiments, etching the portion of the amorphous layer to form the liner layer includes wet etching process using hydrofluoric acid (O₃_HF) etchant.

Accordingly, another aspect of the instant disclosure provides a method of fabricating a semiconductor device that comprises forming a plurality of trenches on a top surface of a substrate; performing a surface treatment process on the substrate; and disposing a conductive material over the dielectric lining layer to fill the trench. The surface treatment process comprises forming an amorphous lining layer on the substrate over exposed surface in the trenches; reducing a thickness of the amorphous lining layer; and converting the amorphous layer at least partially into a dielectric lining layer.

Accordingly, another aspect of the instant disclosure provides a semiconductor structure that comprises a substrate having a plurality of trenches; an amorphous liner layer disposed on a top surface of the substrate and within at least one of the plurality of trenches; and a dielectric liner layer disposed on the amorphous liner layer.

In some embodiments, the plurality of trenches having a first set of trenches and a second set of trenches and the amorphous liner layer only disposed in the first set of trenches.

In some embodiments, the structure further comprises a supplementary liner layer disposed between the substrate and the dielectric liner layer.

In some embodiments, a thickness of the amorphous liner layer is about 30 Å.

In some embodiments, the plurality of trenches having substantially same depth from a top surface of the substrate.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming an oxide, comprising:
forming a first set of trenches on a top surface of a substrate; and
performing a surface treatment on the substrate, the surface treatment process comprising:
forming an amorphous layer on the substrate;
etching a portion of the amorphous layer to form a liner layer, wherein the amorphous layer is thicker than the liner layer; and
disposing a dielectric material on the liner layer.

2. The method of claim 1, further comprising:
forming a second set of trenches on a top surface of a substrate.

3. The method of claim 2, wherein a distance of a bottom of the first set of trenches from the top surface of the substrate are greater than a distance of a bottom of the second set of trenches from the top surface of the substrate.

4. The method of claim 2, wherein the first set of trenches and the second set of trenches are formed simultaneously.

5. The method of claim 2, further comprising:
repeating the surface treatment after forming the second set of trenches.

6. The method of claim 2, wherein a width of an opening of the first set of trenches is greater than a width of opening of the second set of trenches.

7. The method of claim 1, wherein forming the amorphous layer on the substrate is depositing an amorphous material on the top surface of the substrate using chemical vapor deposition.

8. The method of claim 1, wherein the first set of trenches does not penetrate through a bottom surface of the substrate.

9. The method of claim 1, wherein a thickness of the amorphous layer is at least 100 Å.

10. The method of claim 1, wherein a thickness of the liner layer is less than 30 Å.

11. The method of claim 1, wherein a thickness of the amorphous layer is about 3 to 5 times a thickness of the liner layer.

12. The method of claim 1, wherein etching the portion of the amorphous layer to form the liner layer includes wet etching process using Standard Cleaning 1 (SC1) etchant.

13. The method of claim 12, wherein the SC1 etchant includes at least one of NH₄OH, H₂O₂, and di-ionized water.

14. The method of claim 1, wherein etching the portion of the amorphous layer to form the liner layer includes wet etching process using hydrofluoric acid (O₃_HF) etchant.

15. A method of fabricating a semiconductor device, comprising:
forming a plurality of trenches on a top surface of a substrate;
performing a surface treatment process on the substrate, the surface treatment process comprising:
forming an amorphous lining layer on the substrate over exposed surface in the trenches;
reducing a thickness of the amorphous lining layer; and
converting the amorphous layer at least partially into a dielectric lining layer; and
disposing a conductive material over the dielectric lining layer to fill the trench.

16. A semiconductor structure, comprising:
a substrate having a plurality of trenches;
an amorphous liner layer disposed on a top surface of the substrate and within at least one of the plurality of trenches; and
a dielectric liner layer disposed on the amorphous liner layer.

17. The structure of claim 16, wherein the plurality of trenches having a first set of trenches and a second set of trenches and the amorphous liner layer only disposed in the first set of trenches.

18. The structure of claim 16, further comprising a supplementary liner layer disposed between the substrate and the dielectric liner layer.

19. The structure of claim 16, wherein a thickness of the amorphous liner layer is about 30 Å.

20. The structure of claim 16, wherein the plurality of trenches having substantially same depth from a top surface of the substrate.
